(19) United States
(12) Patent Application Publication
(10) Pub. No.: US 2026/0126304 A1
(43) Pub. Date: May 7, 2026

(54) Sensor System

(71) Applicant: Hitachi High-Tech Corporation, Tokyo (JP)

(72) Inventors: Dai KANEDA, Tokyo (JP); Naoya Ishigaki, Tokyo (JP)

(21) Appl. No.: 19/329,675

(22) Filed: Sep. 16, 2025

(30) Foreign Application Priority Data
Nov. 5, 2024 (JP) 2024-193954

(51) Int. Cl. G01D 5/16; H03K 5/24; H03K 17/00; H03K 17/18; H03K 19/20

(52) U.S. Cl. CPC G01D 5/16; H03K 5/2463; H03K 17/005; H03K 17/18; H03K 19/20

(57) ABSTRACT

A sensor system according to the present invention includes a sensor unit that is formed of a pair of a sensor and an electronic circuit unit for each of the sensors, switching circuits in the electronic circuit units are connected in series, and the electronic circuit units are configured such that, when outputs from all the sensors are normal, all the switching circuits are electrically connected in series.

### BACKGROUND OF THE INVENTION

### 1. Field of the Invention

The present invention relates to a sensor system where a plurality of sensors are connected.

### 2. Description of Related Art

A sensor system where a plurality of sensors are connected in parallel to one monitoring device can monitor each of the sensors without requiring a complicated algorithm, but has poor extensibility. In addition, as the scale of the system increases, the number of sensors required increases. In this environment, there is a problem such as an increase in the number of wirings or complication of a wiring path.

In order to solve this problem, as a technique of improving extensibility, cost benefit, and maintenance, a technique where sensors are connected in series to a monitoring device is present. There are various connection methods between the monitoring device and the sensors, and one examples thereof is disclosed in JP2001-067575A.

JP2001-067575A provides a sensor system where a plurality of sensors are connected in series assuming that the sensor that detects ON/OFF is mounted. Until now, in the system where a plurality of sensors are connected in series, it has been difficult to accurately detect the position of the sensor that executes the ON/OFF operation. The position detection herein refers to a technique of specifying the number of position where any sensor is positioned in the sensor system where a plurality of sensors are connected in series. JP-A-2001-067575 provides a solution by transmitting and receiving a pulse train using a central monitoring device. That is, by associating each of the sensors with a count value of the pulse train and processing a signal from the sensor in a time-division manner, the position detection of the sensor can be executed.

However, the sensor system of JP2001-067575A is limited to application to the sensor that detects ON/OFF, and cannot be applied to an analog sensor that detects a physical change such as a temperature, a pressure, or a humidity and outputs a voltage signal proportional to the amount of change. The reason for this is that the output from the analog sensor is not a binary value such as ON/OFF.

On the other hand, in the analog sensor system, for example, when a consistent process environment is required as in a semiconductor inspection device, it is very important to keep an environmental variable such as a temperature, a humidity, or a pressure constant, and a subtle change in environment condition directly affects the quality of a product. Under these circumstances, comprehensive monitoring is required for the inside of a device including an analog sensor that detects changes in various physical quantities such as temperature, a humidity, and a pressure in the device and outputs the detected changes as electric signals. Further, abnormality detection of one point on the sensor system may affect the entire process. Therefore, determination of the overall stability of the sensor system takes precedence over individual position specifying.

### SUMMARY OF THE INVENTION

The present invention has been made in consideration of the above-described problems, and an object thereof is to determine an overall state of a sensor system using an output of a signal terminal of one point in the sensor system where sensor units on which an analog sensor is mounted are connected in series.

A sensor system according to the present invention includes a sensor unit that is formed of a pair of a sensor and an electronic circuit unit for each of the sensors, switching circuits in the electronic circuit units are connected in series, and the electronic circuit units are configured such that, when outputs from all the sensors are normal, all the switching circuits are electrically connected in series.

With the sensor system according to the present invention, an overall state of the sensor system can be determined using an output of a signal terminal of one point in the sensor system where sensor units on which an analog sensor is mounted are connected in series.

### BRIEF DESCRIPTION OF THE DRAWINGS

FIG. 1 is a block diagram illustrating a sensor system 10 according to a first embodiment;

FIG. 2 is a block diagram illustrating a configuration of each sensor unit and connection between the sensor units;

FIG. 3 is a block diagram illustrating a configuration of a switching circuit;

FIG. 4 is a waveform chart illustrating a relationship between signals in the first embodiment;

FIG. 5 is a block diagram illustrating a configuration of a switching circuit according to a second embodiment; and

FIG. 6 is a waveform chart illustrating a relationship between signals in the second embodiment.

### DESCRIPTION OF EMBODIMENTS

### First Embodiment

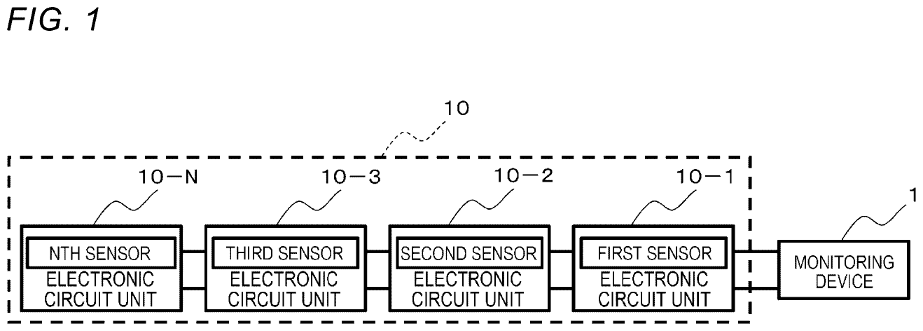

FIG. 1 is a block diagram illustrating a sensor system 10 according to a first embodiment of the present invention. The sensor system 10 is configured with a plurality of sensor units. Each of the sensor units is configured with a sensor (for example, analog sensor) and an electronic circuit unit. The sensor units 10-1, 10-2, 10-3, . . . , and 10-N are electrically connected in series.

By monitoring a voltage value output from the first sensor unit 10-1, a monitoring device 1 can determine a stable state or an abnormal state of each of the sensors mounted on the sensor system 10. Further, in the abnormal state, an output voltage of the sensor at a position where an abnormality occurs can be checked.

“Stable state” described herein refers to a state where an output voltage of the sensor is maintained at a constant value over time without substantially varying unless an external condition changes. “Abnormal state” refers to a state where an output voltage of the sensor deviates from an expected range and shows an unexpected variation or an abnormal value.

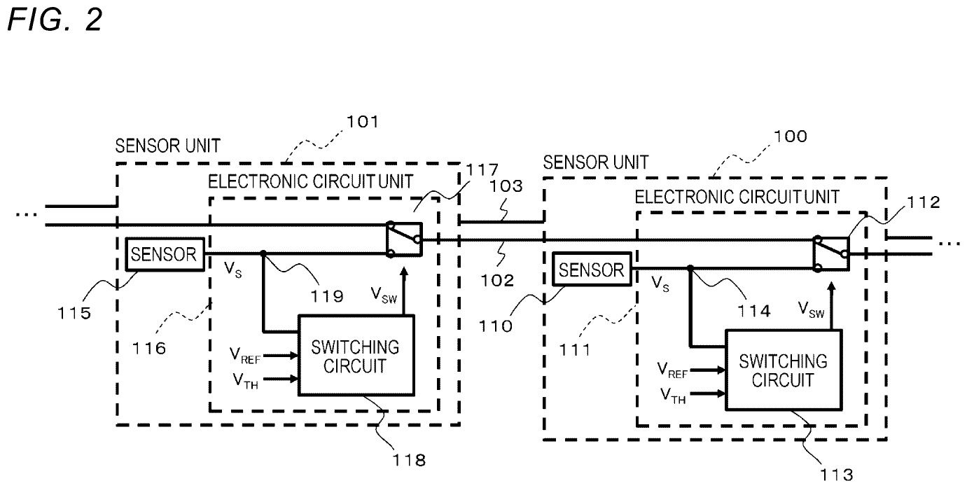

FIG. 2 is a block diagram illustrating a configuration of each sensor unit and connection between the sensor units. An Nth sensor unit 100 is electrically connected to an N+1th sensor unit 101. Each of the sensor units is configured with the same content. The description will be made using the sensor unit 100 as an example. The sensor unit 100 includes a sensor 110 and an electronic circuit unit 111, and the electronic circuit unit 111 is configured with a switch 112 (for example, a single-pole double-throw switch) and a switching circuit 113. A sensor 115, an electronic circuit unit 116, a switch 117, and a switching circuit 118 are also configured as described above.

The switch 112 includes two terminals on the input side and one terminal on the output side, one terminal on the input side is electrically connected to an output of the switch 117 in the electronic circuit unit 116 provided in the N+1th sensor unit 101 (line 102), and the other terminal on the input side is electrically connected to an output voltage V_{S} of the sensor 110 provided in the Nth sensor unit 100. The output side is output to the outside of the Nth sensor unit 100, is electrically connected to one terminal of the input of the switch in the electronic circuit unit provided in an N−1th sensor unit when N≥2, and is electrically connected to a monitoring device or the like when N=1.

The switch 112 is switched in response to an output V_{SW} of the switching circuit 113 as a trigger. The switch 112 is switched such that, when V_{S} is in the stable state, the line 102 and an output of the switch 112 are electrically connected, and when V_{S} is in the abnormal state, V_{S} and the output of the switch 112 are electrically connected.

The switching circuit 113 receives as an input, V_{S} branched at a node 114, a fixed voltage V_{REF} having the same value as an output voltage value when the sensor 110 is in the stable state, and a threshold voltage V_{TH}. The details of V_{REF} and V_{TH} will be described below. V_{SW} only needs to be used as the trigger for the switching of the switch 112, and may not be directly electrically connected to the switch 112. With the above-described configuration, when the sensor in any sensor unit is in the abnormal state, a voltage value of the sensor is output from the first sensor unit, and the monitoring device checks whether the voltage value is a voltage value in the stable state or a voltage value in the abnormal state. As a result, the stable state or the abnormal state of the sensor mounted on each of the sensor units can be determined.

When a plurality of sensors are simultaneously in the abnormal state, a voltage value of the sensor at the closest position to the monitoring device among the sensors in the abnormal state is transmitted to the output of the first sensor unit. When all the sensors are in the stable state, the sensors are connected in series up to an open end of the switch in the sensor unit at the farthest position from the monitoring device. Therefore, the output of the sensor unit is 0 V.

A line 103 is a line configured to supply power to each of the sensor units, and is preferably wired in series to prevent loss of an advantage of wire-saving that is one characteristic of the present application. The line 103 is provided separately from the line 102. The reason for this is that the line 102 has a function of propagating an abnormal output level from the sensor as it is, and thus is not suitable for use as a power line.

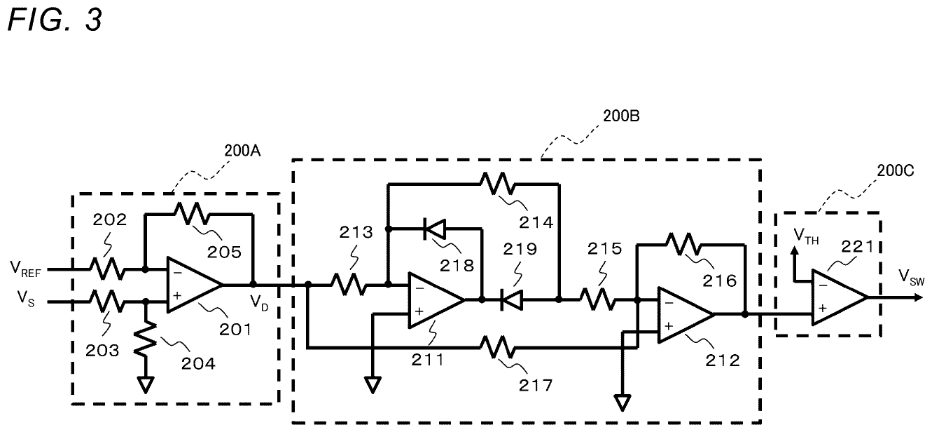

FIG. 3 is a block diagram illustrating a configuration of the switching circuit. The switching circuit is configured with a differential amplifier circuit 200A, an absolute value circuit 200B, and a comparator circuit 200C.

The differential amplifier circuit 200A includes a first operational amplifier 201, a first resistor 202, a second resistor 203, a third resistor 204, and a fourth resistor 205. One terminals of the first resistor 202 and the fourth resistor 205 are electrically connected to an inverting input terminal (-) of the first operational amplifier 201, one terminals of the second resistor 203 and the third resistor 204 are electrically connected to a non-inverting input terminal (+) of the first operational amplifier 201, and one terminal of the fourth resistor 205 is electrically connected to an output of the first operational amplifier 201. One terminal of the third resistor 204 is grounded. One terminal of the first resistor 202 is used for receiving the fixed voltage V_{REF} having the same value as the output voltage value when the sensor is in the stable state. One terminal of the second resistor 203 is used for receiving the output voltage V_{S} of the sensor. Since the principle of the differential amplifier circuit 200A is well-known, the detailed description thereof will not be made.

With the above-described configuration, V_{D}=(V_{S}−V_{REF})×(Amplification Degree) is output to the output of the first operational amplifier 201. Based on this output, the amount of change of the output voltage V_{S} of the sensor from V_{REF} can be detected. That is, when V_{S}>V_{REF}, V_{D} outputs the amount of change as a positive voltage value, and when V_{S}<V_{REF}, V_{D} outputs the amount of change as a negative voltage value.

V_{REF} is any voltage value that is determined depending on an output voltage specification and an installation environment of the sensor. V_{REF} may be generated by dividing a supply voltage to the sensor unit, and can be easily adjusted for each of the sensor units by using a trimmer resistor.

The output voltage of the sensor is limited to a certain range depending on the output voltage specification and the installation environment of the sensor. Therefore, the amplification degree that is determined by a power supply of the first operational amplifier 201, the first resistor 202, and the fourth resistor 205 may be adjusted depending on the output voltage range of the sensor.

The absolute value circuit 200B includes a first operational amplifier 211, a second operational amplifier 212, a first resistor 213, a second resistor 214, a third resistor 215, a fourth resistor 216, a fifth resistor 217, a first diode 218, and a second diode 219.

One terminals of the first resistor 213 and the second resistor 214 and a cathode of the first diode 218 are electrically connected to an inverting input terminal (−) of the first operational amplifier 211. A non-inverting input terminal (+) of the first operational amplifier 211 is grounded. An anode of the first diode 218 and a cathode of the second diode 219 are electrically connected to an output of the first operational amplifier 211. One terminals of the second resistor 214 and the third resistor 215 are electrically connected to an anode of the second diode 219. One terminals of the third resistor 215, the fourth resistor 216, and the fifth resistor 217 are electrically connected to an inverting input terminal (−) of the second operational amplifier 212. A non-inverting input terminal (+) of the second operational amplifier 212 is grounded. An output of the second operational amplifier 212 is electrically connected to one terminal of the fourth resistor 216. One terminal of the first resistor 213 and one terminal of the fifth resistor 217 are electrically connected. One terminal of the first resistor 213 is used for receiving an output voltage V_{D} of the differential amplifier circuit 200A. Since the principle of the absolute value circuit is well-known, the detailed description thereof will not be made.

With the above-described configuration, an absolute value V_{A} of V_{D} is output from the output of the second operational amplifier 212. This configuration is for inverting a signal to operate the comparator circuit described below when a negative voltage is output to V_{D}, and the absolute value circuit 200B is not necessarily required. For example, in a sensor unit on which a general temperature sensor is mounted, in a case where only a temperature increase in the installation environment needs to be detected, even when V_{D} outputs a negative value, there is no effect on the circuit operation. Therefore, the absolute value circuit 200B is not required.

The comparator circuit 200C includes a first comparator 221. An inverting input terminal (−) of the first comparator 221 is used for receiving a threshold voltage V_{TH} described below. A non-inverting input terminal (+) of the first comparator 221 is used for receiving an output V_{A} of the absolute value circuit. An output of the first comparator 221 outputs a voltage V_{SW} used as a trigger of the switch switching.

With the above-described configuration, when V_{A}<V_{TH}, V_{SW} is not output, and when V_{A}>V_{TH}, V_{SW} is output. The threshold voltage V_{TH} is a voltage value that determines a threshold for the degree to which V_{S} is required to vary from V_{REF} for switching the switch, and is any fixed value that is determined depending on an output voltage specification, an installation environment, and a design concept of the sensor. The threshold voltage V_{TH} may be generated by dividing a supply voltage to the sensor unit, and can be easily adjusted for each of the sensor units by using a trimmer resistor.

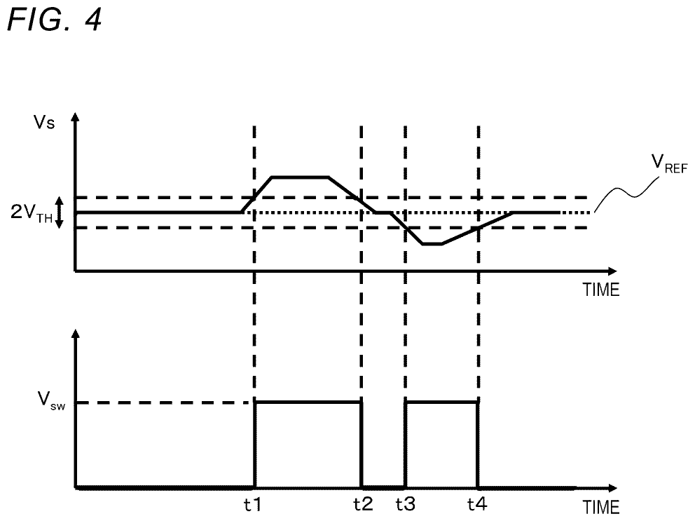

FIG. 4 is a waveform chart illustrating a relationship between signals in the first embodiment. The upper stage of FIG. 4 illustrates a waveform of the output voltage V_{S} of the sensor 110 in the Nth sensor unit 100 illustrated in FIG. 2. The lower stage of FIG. 4 is a waveform representing the degree to which the output V_{SW} of the switching circuit 113 illustrated in FIG. 2 is synchronized with V_{S} illustrated in the upper stage of FIG. 4. V_{REF} is a fixed voltage input to the switching circuit 113 in the Nth sensor unit 100 illustrated in FIG. 2. V_{TH} is a threshold voltage input to the switching circuit 113 in the Nth sensor unit 100 illustrated in FIG. 2. In FIG. 4, the vertical axis represents a voltage, and an arrow direction represents a direction in which an absolute value of a positive voltage increases. The horizontal axis represents the time, and represents a time-series change of the waveform in FIG. 4.

Until time t1, V_{S} falls within a range of 2V_{TH} with respect to V_{REF} as a central axis. At this time, the sensor is determined to be in the stable state, and V_{SW} is not output.

In a period from time t1 to time t2, V_{S} increases to the positive voltage side, and deviates from the range of 2V_{TH} with respect to V_{REF} as the central axis. At this time, the sensor is determined to be in the abnormal state, and V_{SW} is output.

In a period from time t2 to time t3, V_{S} falls again within the range of 2V_{TH} with respect to V_{REF} as the central axis, and V_{SW} is not output.

In a period from time t3 to time t4, V_{S} decreases to the negative voltage side, and deviates from the range of 2V_{TH} with respect to V_{REF} as the central axis. At this time, the sensor is determined to be in the abnormal state, and V_{SW} is output. The output of V_{SW} during the decrease to the negative voltage side is the effect obtained when the absolute value circuit 200B is provided in the switching circuit 113.

In a period after time t4, V_{S} falls again within the range of 2V_{TH} with respect to V_{REF} as the central axis, and V_{SW} is not output.

### First Embodiment: Summary

The sensor system according to the first embodiment includes a sensor unit that is formed of a pair of a sensor and an electronic circuit unit for each of the sensors, in which switching circuits in the electronic circuit units are connected in series, and the electronic circuit units are configured such that, when outputs from all the sensors are normal, all the switching circuits are electrically connected in series. With this circuit configuration, a sensor output can be inspected without using an arithmetic device such as a processor. As a result, with the simple circuit configuration, it can be detected that all the sensor outputs are normal.

In the sensor system according to the first embodiment, when an output from the sensor in the same sensor unit is abnormal, the electronic circuit unit switches the switching circuit such that the sensor output is input to the switching circuit. As a result, when any of the sensor outputs is abnormal, the switch output from the final stage (the sensor unit 10-1 in FIG. 1) is at the abnormal level of the sensor output. Accordingly, with the simple circuit configuration, it can be detected that any of the sensor outputs is abnormal.

Second Embodiment

In the first embodiment, it is assumed that there is a difference between voltage value in the stable state and the voltage value in the abnormal state in each of the sensors. For example, in the first embodiment, when the voltage value in the stable state of the sensor 110 and the voltage value in the abnormal state of the sensor 115 are the same, only with the voltage value appearing on the output of the first sensor unit, the stable state or the abnormal state of the sensor system cannot be determined. As this solution, a second embodiment of the present invention is provided.

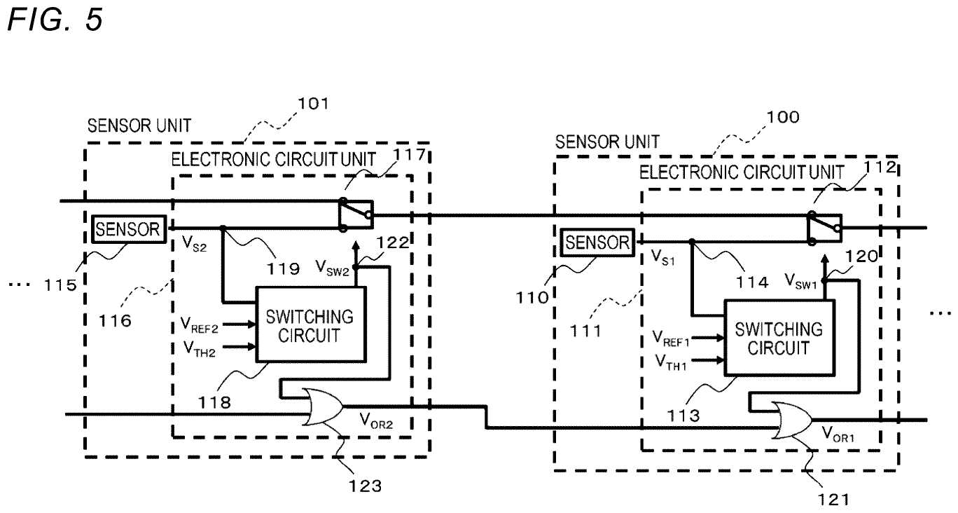

FIG. 5 is a block diagram illustrating a configuration of the switching circuit according to a second embodiment. Since FIG. 5 is similar to FIG. 2, differences will be mainly described. A main difference is that an OR logic element is added to the electronic circuit unit in FIG. 5.

In the configuration illustrated in FIG. 2, the output signal V_{SW} is used only as the trigger for switching the switch. On the other hand, in FIG. 5, V_{SW1} is branched at a node 120, and is input to one terminal of an input of an OR logic element 121. An input of the other terminal of the OR logic element 121 is electrically connected to an output of an OR logic element 123 in the N+1th sensor unit 101. An output of the OR logic element 121 is electrically connected to one terminal of the input of the switch in the electronic circuit unit provided in the N−1th sensor unit when N≥2, and is electrically connected to a monitoring device or the like when N=1.

With the above-described configuration, even when the voltage value in the stable state and the voltage value in the abnormal state between the sensors are the same, the stable state or the abnormal state can be determined based on the output signal of the OR logic element. The reason for this is that, when any of the sensors is in the abnormal state, the OR circuit in the sensor unit including the sensor outputs a high level, and thus the output of the OR circuit of the final stage is also at a high level. Note that the switching circuit can propagate the abnormal output level from the sensor as it is, whereas the OR circuit only shows whether or not an abnormality is present. Therefore, it is desirable that the OR circuit is used as an option when the normal output level and the abnormal output level of the sensors are the same.

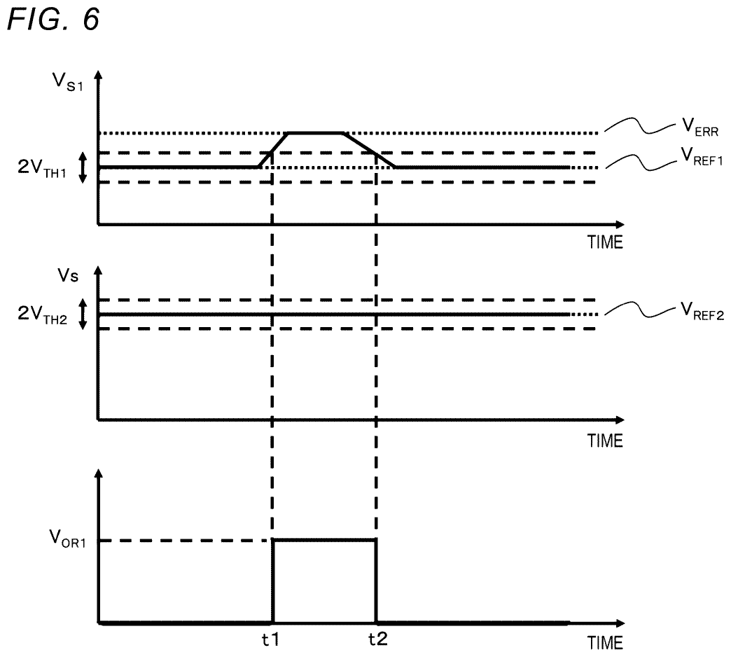

FIG. 6 is a waveform chart illustrating a relationship between signals in the second embodiment. The upper stage of FIG. 6 illustrates a waveform of an output voltage V_{S1} of the sensor 110 in the Nth sensor unit 100 illustrated in FIG. 5. The middle stage of FIG. 6 illustrates an output voltage V_{S2} of the sensor in the N+1th sensor unit illustrated in FIG. 5. The lower stage of FIG. 6 illustrates a waveform representing the degree to which an output V_{OR1} of the OR logic element 121 illustrated in FIG. 5 is synchronized with V_{S1} and V_{S2}.

V_{REF1} is a fixed voltage input to the switching circuit 113 in the Nth sensor unit 100 illustrated in FIG. 5. V_{TH1} is a threshold voltage input to the switching circuit 113 in the Nth sensor unit 100 illustrated in FIG. 5. V_{ERR} is, for example, a voltage value when V_{S1} is in the abnormal state. V_{REF2} is a fixed voltage input to the switching circuit 118 in the N+1th sensor unit 101. V_{TH2} is a threshold voltage input to the switching circuit 118 in the N+1th sensor unit 101. The sensor 110 in the Nth sensor unit 100 and the sensor 115 in the N+1th sensor unit 101 are different sensor types, and V_{ERR}=V_{REF2}.

In FIG. 6, the vertical axis represents a voltage, and an arrow direction represents a direction in which an absolute value of a positive voltage increases. The horizontal axis represents the time, and represents a time-series change of the waveform in FIG. 6.

Until time t1, V_{S1} falls within a range of 2V_{TH1} with respect to V_{REF1} as a central axis, and V_{S2} falls within a range of 2V_{TH2} with respect to V_{REF2} as a central axis. At this time, the sensor is determined to be in the stable state, and V_{OR1} is not output.

In a period from time t1 to time t2, V_{S1} increases to the positive voltage side, and deviates from the range of 2V_{TH1} with respect to V_{REF1} as the central axis. At this time, V_{S1} is transmitted to the monitoring device, and V_{OR} is also output. Since V_{ERR}=V_{REF2}, the monitoring device cannot determine whether the transmitted voltage value is the voltage value in the abnormal state of the sensor 110 or the voltage value in the stable state of V_{S2}. In this case, by reading the V_{OR} signal, the stable or abnormal state can be determined.

That is, when the V_{OR} signal is output, the voltage value transmitted to the monitoring device is the voltage value in the abnormal state, and when the V_{OR} signal is not output, the voltage value transmitted to the monitoring device is the voltage value in the stable state.

### Second Embodiment: Summary

In the sensor system according to the second embodiment, each of the electronic circuit units includes an OR circuit, and the output of the OR circuit is connected to the input of the OR circuit of the next stage. The signal for switching the switching circuit is input to the other input of the OR circuit. As a result, when any of the sensor outputs is abnormal, a signal representing the abnormality is output from the OR circuit of the final stage (the sensor unit 10-1 in FIG. 1). Even in a case where the sensor output levels that are considered to be abnormal are different between the sensors, when any of the sensor outputs is abnormal, the output from the OR circuit is necessarily output. Accordingly, in the second embodiment, the output voltage specifications and the sensor installation environments of the sensors do not need to be made uniform between the sensor units.

### Regarding Modification Example of Present Invention

The present invention is not limited to the embodiments and includes various modification examples. For example, the embodiments have been described in detail in order to easily describe the present disclosure, and the present invention is not necessarily to include all the configurations described above. In addition, a part of the configuration of one embodiment can be replaced with the configuration of another embodiment. Further, the configuration of one embodiment can be added to the configuration of another embodiment. In addition, addition, deletion, and replacement of another configuration can be made for a part of the configuration of each of the embodiments.

What is claimed is:

1. A sensor system comprising a plurality of sensors,
wherein a sensor unit that is formed of a pair of the sensor and an electronic circuit unit is provided for each of the sensors,
each of the electronic circuit units includes a switching circuit,
the switching circuits are connected in series, and
the electronic circuit units are configured such that, when outputs from all the sensors are normal, all the switching circuits are electrically connected in series.

2. The sensor system according to claim 1,
wherein the switching circuit includes a first input terminal, a second input terminal, and an output terminal, and is configured to be switched such that any of a signal input to the first input terminal or a signal input to the second input terminal is output from the output terminal,
the output terminal in the switching circuit is connected to the first input terminal of the switching circuit in the electronic circuit unit of a next stage such that the switching circuits are connected in series,
the second input terminal in the sensor unit is connected to an output of the sensor in the same sensor unit, and
when the output from the sensor in the same sensor unit is normal, the switching circuit in the sensor unit is switched such that the input to the first input terminal is output from the output terminal.

3. The sensor system according to claim 2,
wherein when the output from the sensor in the same sensor unit is abnormal, the switching circuit in the sensor unit is switched such that the input to the second input terminal is output from the output terminal.

4. The sensor system according to claim 2,
wherein the electronic circuit unit includes
a differential amplifier circuit configured to amplify and output a difference between the output from the sensor and a reference signal,
an absolute value circuit configured to output an absolute value of the output signal from the differential amplifier circuit, and
a comparator circuit configured to output a result of comparing the output signal from the absolute value circuit to a threshold voltage,
wherein the electronic circuit unit switches the switching circuit based on the output signal from the comparator circuit.

5. The sensor system according to claim 4,
wherein the comparator circuit switches the switching circuit such that, when the output signal from the absolute value circuit is the threshold voltage or lower, the first input terminal and the output terminal are connected, and when the output signal from the absolute value circuit is higher than the threshold voltage, the second input terminal and the output terminal are connected.

6. The sensor system according to claim 1, further comprising a line configured to connect the electronic circuit units in series to supply power to each of the electronic circuit units,
wherein the line is provided separately from a line configured to connect the switching circuits in series.

7. The sensor system according to claim 1,
wherein the electronic circuit unit includes an OR logic circuit,
a first input terminal of the OR logic circuit receives a switching signal for switching the switching circuit, and
an output terminal of the OR logic circuit is connected to a second input terminal of the OR logic circuit in the electronic circuit unit of a next stage such that the OR logic circuits are connected in series.

8. The sensor system according to claim 7,
wherein the OR logic circuits are connected in series such that, when at least any of outputs of the sensors is abnormal, an output of the OR logic circuit of a final stage is configured to output a signal representing that at least any of the outputs of the sensors is abnormal.
